(19) United States
(12) Patent Application Publication
(10) Pub. No.: US 2005/0035773 A1
(43) Pub. Date: Feb. 17, 2005

(54) Apparatus and method for detecting thermoelectric properties of materials

(75) Inventors: Youqi Wang, Atherton, CA (US); C. Eric Ramberg, San Jose, CA (US); Michael Yee, Mt. Shasta, CA (US)

Correspondence Address: SYMYX TECHNOLOGIES INC;LEGAL DEPARTMENT, 3100 CENTRAL EXPRESS, SANTA CLARA, CA, 95051, US

(73) Assignee: Symyx Technologies, Inc.

(21) Appl. No.: 10/639,008

(22) Filed: Aug. 11, 2003

(51) Int. Cl. G01R 27/08

(52) U.S. Cl. 324/715

(57) ABSTRACT

Apparatus and methods are provided for efficiently and non-destructively determining the thermal properties of materials having arbitrary surface textures. Two regions of a sample are each contacted by respective pairs of probes, where each pair includes a first probe made of a first material and a second probe made of a second material. A voltage sensor is arranged between the two probes of each pair, and between the probes of the same material from each pair. Nodes connect the voltage sensors to the probes. A temperature gradient is established between the two regions, while the nodes are maintained at a constant temperature. The Seebeck coefficient of the material and the temperatures of the regions can be determined from the voltages measured by the voltage sensors.

### CROSS REFERENCE TO RELATED APPLICATIONS

This application is related to U.S. patent application Ser. No. ______ titled “APPARATUS AND METHODS FOR DETERMINING TEMPERATURES AT WHICH PROPERTIES OF MATERIALS CHANGE” attorney docket number 2003-049, filed on the same date as this application.

### FIELD OF THE INVENTION

The present invention relates to an apparatus and method for determining the temperature dependant properties of materials and, more particularly, to an apparatus and method to determine the thermoelectric properties of materials in a non-destructive way.

### BACKGROUND OF THE INVENTION

One of the most important parameters in characterizing the thermoelectric behavior of a material is the thermoelectric coefficient, a, also known as the Seebeck coefficient in the name of the scientist who first identified it. The Seebeck coefficient is an intrinsic property of a material, describing the change of electric potential of a material in responds to a temperature change experienced by the material. Many efforts have been made during the years with the purpose of measuring the thermoelectric coefficients of materials, especially in the field of thermoelectric materials research and development for, e.g. power generation and/or refrigeration applications (see, for example, CRC Handbook of Thermoelectrics, CRC Press (1995)). The ability to measure α is also very important in other industrial sectors, such as metallurgy and the semiconductor industry, including semiconductor materials research, process development, in-line monitoring, and real-time process control, etc., due to the fact that α has a sensitive dependence on band structures, doping species and doping levels, growth conditions, processing conditions etc. Nevertheless, Seebeck coefficient measurements are not commonly used in the semiconductor industry, partially due to the difficulties involved in carrying out such measurements with conventional methods and apparatus.

A prior art assembly for measuring the Seebeck coefficient of a material sample can be exemplified as depicted in FIG. 1. In the prior art setup of FIG. 1, a bar-shaped sample 10 is subjected to a (typically small) temperature difference across its two ends, ΔT=T₂−T₁. The temperatures of the ends are measured by two temperature sensors 11 and 12, typically thermocouple probes. The open-circuit (zero-current) voltage across the sample 10, V, is measured by, e.g., a sensitive voltmeter 13. The result of the measurement is expressed as

$${α}_{R} ( \overline{T} ) \approx \frac{V}{Δ T} , \overline{T} = \frac{1}{2} ( {T}_{1} + {T}_{2} )$$

where α_{R} is the relative Seebeck coefficient of the reference material with respect to a reference material used as the contact pads at a mean temperature \overline{T}. The sign of α_{R} depends on the sign of the voltage reading as well as the direction of the temperature gradient. A further prior art setup for measuring the Seebeck coefficient of thin film samples is disclosed in patent application WO/US99/3008.

However, the known methods and apparatuses for determining Seebeck coefficients of materials have several disadvantages. Conventional setups, such as the one exemplified above, impose restrictions on the sizes, shapes, and surfaces of test specimens. These restrictions preclude arbitrary shaped samples from being tested, and their use can therefore require time and effort to prepare appropriate samples. More seriously, conventional setups cannot be applied directly to thin or thick film samples residing on substrates or wafers without special preparations. Further, the results obtained from conventional measurements are, at best, an average property of the test materials and do not provide a map of Seebeck data across a specimen of interest. Such a map would provide important information about the sample and its growth and/or processing history, which would be useful in the semiconductor fabrication and metallurgy industries as a diagnostic tool as well as in QA/QC applications. Conventional schemes also are not well suited to integration into cluster tools or in-line tools in semiconductor/IC production lines, or into metallurgical production lines, for real-time monitoring and/or in-line process control.

It is therefore highly desirable to provide an apparatus and a method that can overcome the above-mentioned drawbacks.

### SUMMARY OF THE INVENTION

The present invention provides an apparatus for determining a thermoelectric property of a sample, such as may be disposed on a substrate. The apparatus includes first and second probe sets, a positioning device configured to bring the first probe set into contact with a first contact region of the sample and to bring the second probe set into contact with a second contact region of the sample, a voltage measurement system, and detection electronics. The first probe set includes a first electrically conductive probe formed of a first material and a second electrically conductive probe formed of a second material that is different than the first material. Likewise, the second probe set includes a third electrically conductive probe formed of the first material and a fourth electrically conductive probe formed of the second material. The voltage measurement system includes a first voltage sensing device configured to determine a first voltage between the first and third electrically conductive probes, and a second voltage sensing device configured to determine a second voltage between the second and fourth electrically conductive probes. The detection electronics is configured to determine the thermoelectric property of the sample from the first and second voltages. In some embodiments the voltage measurement system further includes a third voltage sensing device configured to determine a third voltage between the first and second electrically conductive probes, and a fourth voltage sensing device configured to determine a fourth voltage between the third and fourth electrically conductive probes. In these embodiments the detection electronics is further configured to determine a first contact region temperature from the third voltage and a second contact region temperature from the fourth voltage. In some embodiments the detection electronics is further configured to simultaneously determine a Seebeck coefficient of the sample and a temperature difference between the first and second contact regions from the first and second voltages.

In some embodiments the first and second materials each have a known Seebeck coefficient data set over a temperature range of interest, and in some embodiments the first and second materials include standard thermocouple materials. The probes may even be adapted from electric contact tips for an electric contact probe station.

In further embodiments the first voltage sensing device is connected to the first electrically conductive probe at a first node maintained at a reference temperature and to the third electrically conductive probe at a second node also maintained at the reference temperature, and the second voltage sensing device is connected to the second electrically conductive probe at a third node maintained at the reference temperature and to the fourth electrically conductive probe at a fourth node also maintained at the reference temperature. In some of these embodiments a third voltage sensing device, configured to determine a third voltage, is connected to the first electrically conductive probe at the first node and to the second electrically conductive probe at the third node, and a fourth voltage sensing device, configured to determine a fourth voltage, is connected to the third electrically conductive probe at the second node and to the fourth electrically conductive probe at the fourth node. In these embodiments the detection electronics is further configured to determine a first contact region temperature from the third voltage and a second contact region temperature from the fourth voltage. In some of these embodiments a thermal block in is contact with the first, second, third, and fourth nodes to maintain the nodes at the reference temperature. Further of these embodiments include a first buffer device between the first voltage sensing device and the first node and a second buffer device between the first voltage sensing device and the second node, and some of these embodiments include a third buffer device between the second voltage sensing device and the third node and a fourth buffer device between the second voltage sensing device and the fourth node, and some of the latter embodiments can include a first differential amplifier configured to receive an output from each of the first and second buffer devices and a second differential amplifier configured to receive an output from each of the third and fourth buffer devices.

Some embodiments of the apparatus of the invention also include a radiation source, to produce a temperature gradient between the first and second contact regions, that can include a laser, an IR source, or a microwave source. Embodiments can also include a drive unit configured to translate the positioning device, the radiation source, or the substrate. In some embodiments at least one electrically conductive probe includes a thermal jacket, and in some the first and second electrically conductive probes are joined together to form a first thermocouple, and in some of these embodiments the third and fourth electrically conductive probes are joined together to form a second thermocouple. Embodiments can also include a non-contact IR sensor to measure a temperature of the first or second contact regions.

The invention also provides a method for determining a thermoelectric property of a sample. The method includes contacting the sample with a set of electrically conductive probes in each of two contact regions where each set of probes including a first probe of a first material and a second probe of a second material different than the first material. The method further includes measuring a first voltage between the first probes and a second voltage between the second probes, and determining the thermoelectric property of the sample from the first and second voltages. In some of these embodiments the method also includes establishing a temperature gradient between the two contact regions. The method can also include measuring a first temperature of a first contact region of the two contact regions and measuring a second temperature of a second contact region of the two contact regions. Some of these embodiments can further include correlating the thermoelectric property to an average temperature of the first and second temperatures. In some embodiments determining the thermoelectric property of the sample includes determining a Seebeck coefficient for the first material at an average temperature, where the average temperature is an average of a first temperature of the first contact region and a second temperature of the second contact region. In some of these embodiments the Seebeck coefficient for the first material at the average temperature is determined from a Seebeck coefficient data set for the first material.

Another method of the invention for determining a thermoelectric property of a sample having first and second regions includes measuring a first voltage between a first interface and a second interface, where the first interface is formed between a first electrically conductive material and the first region, and the second interface is formed between the first electrically conductive material and the second region. The method further includes measuring a second voltage between a third interface and a fourth interface, where the third interface is formed between a second electrically conductive material and the first region, and the fourth interface is formed between the second electrically conductive material and the second region. The method also includes measuring an average temperature of the first and second regions, determining a Seebeck coefficient for the first and second materials at the average temperature, and determining the thermoelectric property of the sample from the first and second voltages and the determined Seebeck coefficients for the first and second materials. In some of these embodiments the method also includes modulating the temperatures of the first and second regions.

Additionally, the invention provides a method for mapping a thermoelectric property of a sample. This method includes determining a grid for a surface of the sample, the grid specifying a number of nodes with a spacing therebetween, and measuring a Seebeck coefficient between nodes of the grid to develop a map.

### BRIEF DESCRIPTION OF THE DRAWINGS

FIG. 1 is a schematic view of a prior art setup for measuring a Seebeck coefficient of a material sample.

FIG. 2 is a schematic view of an apparatus for measuring a Seebeck coefficient according to an embodiment of the invention.

FIG. 3 is a schematic view of an apparatus for measuring a Seebeck coefficient according to another embodiment of the invention.

FIG. 4 is a schematic view of a driving unit for the apparatus of FIG. 3.

FIG. 5 is a perspective view of a probe according to an embodiment of the invention.

FIG. 6 is a schematic electrical diagram of an embodiment of the invention.

FIG. 7 is a perspective view of adjacent probes joined together to form a thermocouple according to an embodiment of the invention.

### DETAILED DESCRIPTION OF THE INVENTION

The present invention is directed to apparatus and methods that can be used to detect the temperature dependent properties of a material, and more specifically, the Seebeck coefficient of a subject material, having an arbitrary shape and size, without any special sample preparation. The apparatus includes two sets of probes that contact the material at different locations and a voltage measurement system configured to measure voltage differences between the probes. Each set of probes includes a first probe of a first material and a second probe of a second, different, material. Voltage measurements between probes of the same material in different probe sets can be used to simultaneously measure the Seebeck coefficient of the material and the temperature differential between the contact locations where the contact locations are at different temperatures. The methods use a voltage measurement between the probes of the same probe set to determine the temperature of the material in the contact location of that probe set.

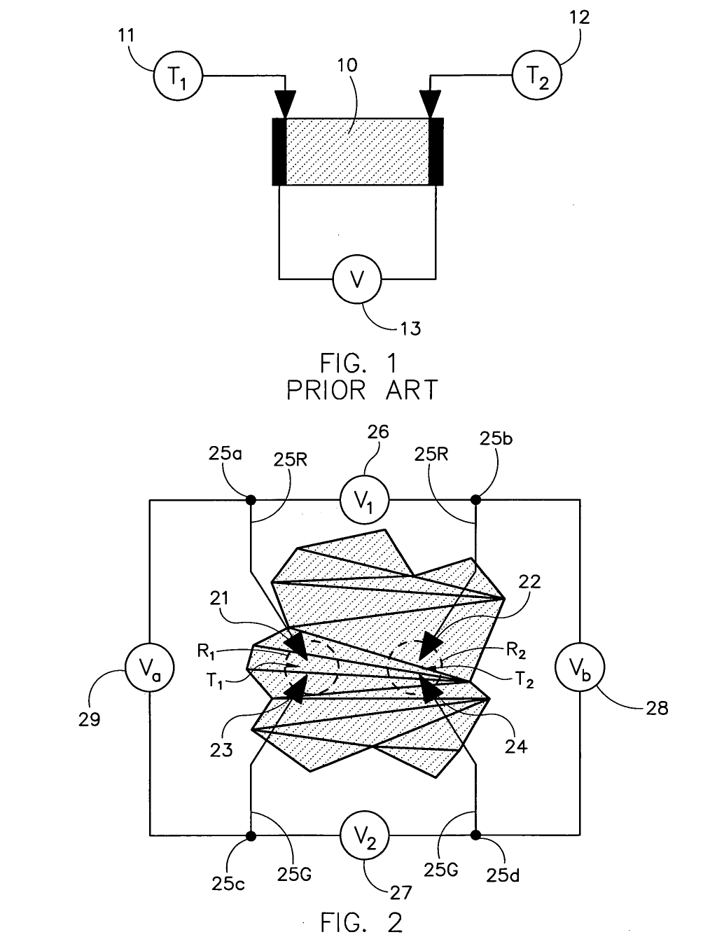

FIG. 2 is a schematic representation of an apparatus according to an exemplary embodiment of the invention for detecting temperature dependent properties of materials. FIG. 2 shows an arbitrary area of a surface of an electrically conductive sample. The sample can be, for example, a metal or a semiconductor, a thin or thick film supported on a substrate, an unsupported membrane, or a bulk sample. The surface of the specimen does not need to be flat, as shown, and can be rough or corrugated microscopically as well as macroscopically. The sample also does not need to be a solid and can be, for example, an electronically conducting liquid, which is distinguishable from an ionically conducting liquid.

Two arrows 21, 22 in FIG. 2 represent a pair of probes such as needles, pins, tips, etc., both made from a first electrically conductive material, such as a metal, having a known Seebeck coefficient data set over a temperature range of interest. The arrows 23, 24 represent a second pair of probes made from a second electrically conductive material, such as another metal, that is different from the material of the probes 21, 22. The second material used to form the probes 23, 24 also has a known Seebeck coefficient data set over the same temperature range of interest, and preferably the Seebeck coefficient data set of the second material differs significantly with respect to the Seebeck coefficient data set of the first material over this temperature range. Suitable materials for the probe pairs include metals and/or alloys commonly used for making standard thermocouples. Probe pairs can also be adapted from commercially available electric contact tips such as those used in electric contact probe stations.

The probes 21, 22, 23, 24 may be brought into contact with the sample surface via mechanical pressure, created by, for instance, springs, arm deformations, deflections, or various other mechanisms that function similarly. The resilient nature of the probes 21, 22, 23, 24 allow them to readily conform to the surface contours of the areas where contacts are made.

The probes 21, 22, 23, 24 are electrically connected to associated extension wires 25R, 25G that are made from essentially the same materials as the probes 21, 22, 23, 24 to which they are attached. Each extension wire 25R, 25G is further connected at a node 25a, 25b, 25c, 25d, to two of the voltage sensing devices 26, 27, 28, 29, as shown in FIG. 2. The nodes 25a, 25b, 25c, 25d are maintained at essentially the same temperature via, e.g., a thermal block (not shown). The temperature of the nodes 25a, 25b, 25c, 25d serves as the reference temperature during the measurement. The choice of the reference temperature is a matter of convenience or custom, such as room temperature, 0° C., etc.

As indicated in FIG. 2, adjacent probes 21, 23 make contact with the sample surface in a first contact region R1 and adjacent probes 22, 24 contact the surface in a second region R2. The average surface temperatures of the contact regions R1 and R2 are indicated as T_{1 and T}₂, respectively. The adjacent probes 21, 23 and 22, 24 are arranged to contact the surface of the sample as close as possible to one another without making direct electric contact between them. In some embodiments the areas of the contact regions range from a few square micrometers to several square millimeters. The spacing between the two contact regions R1, R2 depends on the general properties of the subject material under test and the specific applications involved, and, in addition to practical considerations, such as spatial or mechanical constraints, noise pickup, output impedance of the signal source, etc. Thus, for in-line monitoring and QA/QC applications, the spacing can be a few centimeters to a few tens of centimeters such as across the diameter of a 300 mm wafer, while for mapping applications, the spacing can be on the order of a micron to a few millimeters.

A necessary condition of the Seebeck measurement is that T₁≠T₂. However, ΔT=T₁−T₂ is preferably small, such as from about 0.1 to a few degrees Kelvin. Such a condition can be satisfied in a passive fashion where the sample temperature distribution is non-uniform between the two contact regions, as is often the case in real world environments. However, in many applications it may be preferable to cause a temperature difference by actively heating or cooling the sample in a non-uniform manner, which can be a much easier task, in many instances, than achieving uniform heating or cooling. Any convenient and/or conceivable method may be used to heat or cool the sample, for example, by conduction, convection, radiation, irradiation, resistive heating, etc. In one illustrative embodiment a laser, or other directional energy source, directs a radiation beam towards one of the contact regions R1 or R2 to cause local heating of that area.

The following basic concepts are used to determine thermoelectric properties from the configuration shown in FIG. 2. For simplicity the following assumptions are made. It will be appreciated that the effects neglected by the assumptions can be determined by experiment and/or appropriate calibrations. (1) The sample material is sufficiently uniform or homogeneous within a larger region that includes both of the contact regions R1 and R2. (2) The surface temperature within each contact region R1, R2 is sufficiently uniform and unaffected by contact with the corresponding contacting probes. (3) The temperature difference between the two surfaces that form an interface at any junction or contact point involved in the measurement circuit is sufficiently small that its effect can be neglected. (4) The input impedance of each voltage sensing device 26, 27, 28, 29 is sufficiently high relative to the electric impedance of the circuit loop involved in the measurement and the leakage current of each voltage sensing device 26, 27, 28, 29 is sufficiently low that these effects can be neglected.

With the above assumptions, it is easy to derive that

$${V}_{1} ≅ [ α ( R , \overline{T} ) - α ( S , \overline{T} ) ] Δ T , \overline{T} = \frac{1}{2} ( {T}_{1} + {T}_{2} ) , \\ {V}_{2} ≅ [ α ( G , \overline{T} ) - α ( S , \overline{T} ) ] Δ T , Δ T = {T}_{1} - {T}_{2} \qquad ( 1 )$$

where α(M, T) refers to the Seebeck coefficient of material Mat temperature T, and R refers to the material from which the extension wires 25R are made. G refers to the material from which the extension wires 25G are made, and S refers to the sample material in the contact region R1 and R2. The approximation symbol ≅ emphasizes that the condition that ΔT is sufficiently small enough that the Seebeck coefficients can be treated as constants within ΔT. It thus follows that

$$\begin{matrix}Δ T ≅ \frac{{V}_{1} - {V}_{2}}{α ( R , \overline{T} ) - α ( G , \overline{T} )} and & ( 2 ) \\ α ( S , \overline{T} ) ≅ α ( R , \overline{T} ) - \frac{{V}_{1}}{Δ T} or α ( S , \overline{T} ) ≅ α ( G , \overline{T} ) - \frac{{V}_{2}}{Δ T} . & ( 3 )\end{matrix}$$

Thus, the actual temperature difference ΔT as well as the absolute Seebeck coefficient of the specimen sample at \overline{T} is obtained simultaneously by the measurement of V₁ and V₂, preferably simultaneously, given that the Seebeck data of materials R and G are known.

If the materials R and G are chosen to be common materials used to make standard thermocouple pairs, e.g., K-type, C-type, etc., then, the value, Δα(T)=α(R,\overline{T})−α(G,\overline{T}), can be obtained by taking the temperature derivative of the standard thermocouple EMF data (readily available from e.g., the NIST web site) over the applicable temperature range. Then

$${α}_{R , R} ( S , \overline{T} ) = α ( S , \overline{T} ) - α ( R , \overline{T} ) = - \frac{{V}_{1}}{Δ T} \\ {α}_{R , G} ( S , \overline{T} ) = α ( S , \overline{T} ) - α ( G , \overline{T} ) = - \frac{{V}_{2}}{Δ T} \qquad ( 4 )$$

where α_{R,R}(S,\overline{T}) is the relative Seebeck coefficient of the sample with respect to the reference material R, vide infer.

There are variety of means to measure or estimate T₁, T₂, and/or \overline{T} such as by using a non-contact IR sensor. In preferred embodiments, it is just as convenient to measure Vₐ and V_{b} which are the electromotive force readings (EMF) of T₁ and T₂, measured at voltage sensing device 29 and 28, respectively, of the thermocouple pair R/G, composed of the materials R and G, with respect to the reference temperature T₀. If the materials R and G are chosen to be standard thermocouple materials, then the temperatures T₁ and T₂, and hence \overline{T}, are readily obtainable.

To obtain a Seebeck coefficient map of a specimen, an apparatus of the invention imposes a virtual grid upon the surface of the specimen and then sequentially considers sets of nodes on the grid to be the contact regions R1 and R2. By making measurements at each node of the grid, a map of the Seebeck coefficient across the specimen is developed. To verify the homogeneity of a specimen within a grid area, the apparatus makes small variations in the spacing between the contact regions R1 and R2, and/or small changes in the orientation of the vector linking R1 and R2 with respect to the specimen, and compares the measurement results. To verify the temperature uniformity within each contact region R1, R2, the apparatus performs multiple measurements in approximately the same areas, removing the probes from the surface between measurements. To test the validity of the approximation in Eq. (1), an active temperature managing device may be used to alter T₁ and/or T₂ while measuring V₁ and V₂. If the temperature is modulated sinusoidally, phase-sensitive detection techniques can be used to increase sensitivity and/or to reduce noise. While V₁ and V₂ will oscillate in response to temperature modulation, the voltage ratio, V₁/(V₁−V₂), should remain constant if the modulation amplitude is sufficiently small.

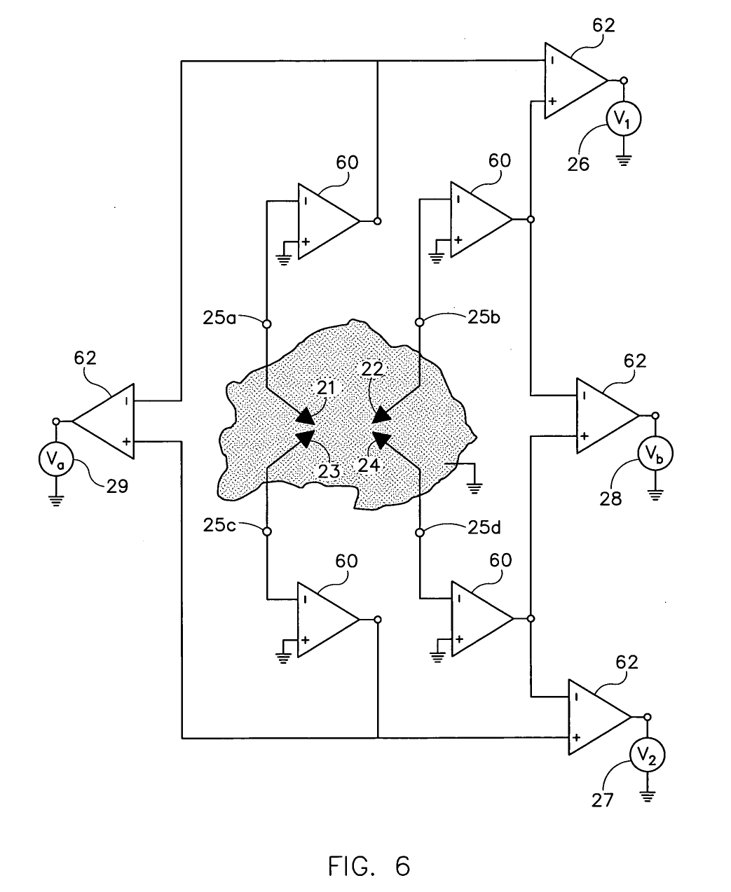

If the temperature near the tip of a probe is different from the temperature of a contact region R1 or R2, a net heat flux across the interface will occur, which will cause an error in the measurement. This error becomes more severe when the temperature of the contact region R1 or R2 is significantly higher or lower than the ambient temperature, or when the specimen is a thin or thick film on a substrate or in membrane-like form. Using a probe with smaller cross-section may reduce this type of error but cannot eliminate it completely. Small cross-section probes also lack mechanical strength, which is disadvantageous in certain applications. A better solution, therefore, is to actively control the temperature of the probes such that the temperature near the tip of a probe is essentially identical to the temperature of the corresponding contact region R1 or R2. In some embodiments, this is accomplished by including a thermal jacket 50 around each probe 52, as depictured in FIG. 5, and the temperature of the thermal jacket 50 is actively controlled to be essentially equal to the temperature of the corresponding contact region R1 or R2 measured by Vₐ or V_{b}, respectively. The exposed portion near the tip of the probe 52 is also minimized to reduce heat exchange of the probe 52 with the environment through convection and/or radiation pathways.

Most commercial voltage sensing devices can have a suitable input impendence, typically about 10 GΩ or higher. However, a measurement error can occur if a leakage current is not sufficiently small, especially for semiconductor thin films where the source impendence can be as high as several MΩ. Thus, if the leakage current, also known as an input bias current, is about 10 pA, the error caused by the input bias current can be on the order of 10 mV, which is a significant amount of error for many applications.

One exemplary solution to solve the problem, shown in FIG. 6, is to insert a buffer device 60 between each node 25a, 25b, 25c, 25d and the corresponding voltage sensing devices 26, 27, 28, 29. The buffer devices 60, which in some embodiments are operation amplifiers, are designed to have a low fixed gain, and are specially chosen for their extremely low leakage current, on the order of 50 fA or less. The buffer devices 60 are located proximate to the nodes 25a, 25b, 25c, 25d and reside inside a temperature bath enclosure (which is a specific example of a thermal block), the temperature of which is tightly controlled with a thermoelectric heating/cooling device to, for instance, 0° C.±0.01° C., in order to minimize the thermal drift of the offset voltage which is typically high for ultralow bias current operation amplifiers. Further, each buffer device 60 can include an offset voltage compensation circuit (not shown) to cancel the offset voltage inherent to the buffer device 60. Cancellation is achieved by a summing amplifier having a voltage opposite to the bias voltage that is derived from a precision voltage reference either by analog means or by digital control signals from a control computer. The outputs of the buffer devices 60 are further fed into 4 differential amplifiers 62, as shown. The outputs of the differential amplifiers 62 correspond to amplified versions of V₁, V₂, Vₐ, and V_{b} and can be connected to multiple voltage sensing devices or switchably connected to a single voltage sensing device. The subject specimen is preferably grounded through a dedicated passage to the common ground of the buffer devices 60 to protect them from possible over-voltage damage.

In the above-described embodiments two pairs of probes are involved, i.e., probes 21, 22 and probes 23, 24. This is the most compact arrangement and should be sufficient in many situations. Alternatively, a third pair of probes made from a third material can be introduced and brought into the same contact regions R1 and R2, with their voltages measured accordingly. The additional voltage information makes the ΔT and Δ(S,\overline{T}) measurements over-determined. Hence, any inconsistency among the results obtained from the different sets of voltage data may suggest some non-uniformity within the contact regions R1, R2, or improper contact between a probe and the contact region R1, R2 caused by, e.g., contamination by dust or a surface coating (silicone oil, oxidation layer, etc.) on a probe or the contact region R1 or R2, a chemical reaction between the probe and the contact region R1 or R2, or an instrument or system related problem. Alternatively, one may use the additional data to improve the accuracy of the measurement. In principle, the addition of more pairs of probes made from a same or different materials may further improve the measurement reliability and accuracy. In practice, however, the ability to implement further probes is constrained by spatial and mechanical limitations as well as the complexity of the measurement system.

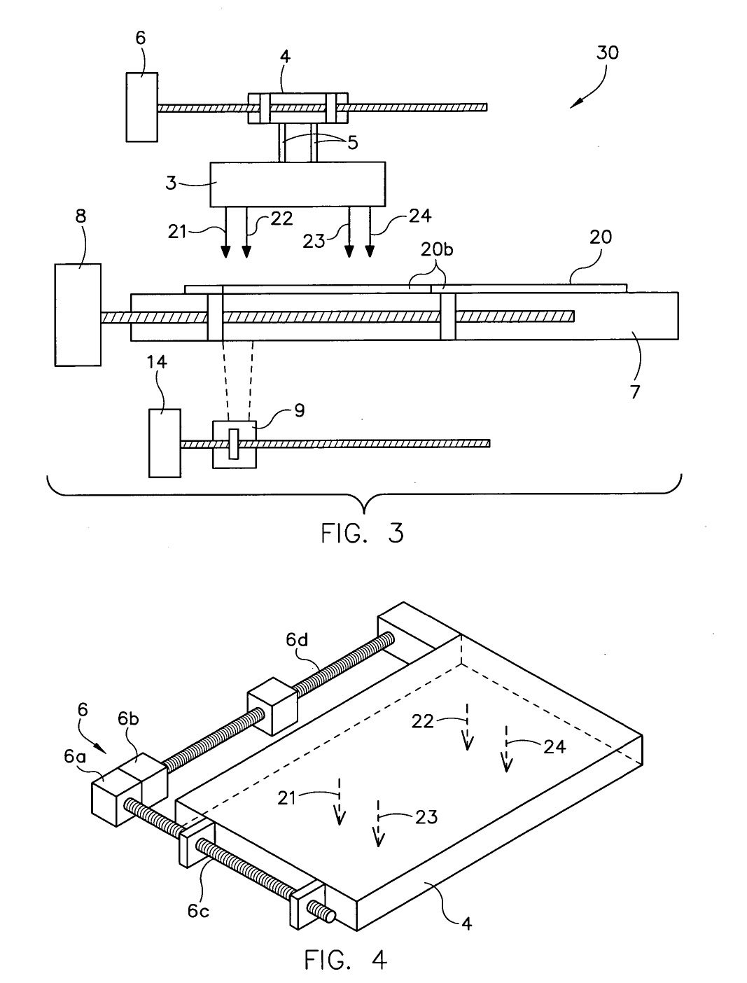

FIG. 3 shows an exemplary embodiment of an apparatus 30 for measuring the temperature dependent properties of a library of materials. In FIG. 3, the parts similar to those depicted in FIG. 2 are identified by the same reference numerals and a detailed description thereof is accordingly omitted. In FIG. 3, a substrate 20 to be tested is depicted as being composed of different portions 20b. Portions 20b can be, for example, discrete samples disposed in an array on the substrate 20, or different phases or spots of the substrate 20 itself. In some embodiments the substrate 20 is, for example, a silicon or quartz wafer configured to support a library of thin-film portions 20b. In other embodiments the substrate 20 can include wells or other features to allow liquid portions 20b to be retained.

Also shown in FIG. 3 is a positioning device adapted to bring the probes 21, 22, 23, 24 into contact with the substrate 20 at predefined locations. To this end, the positioning device comprises a supporting head 3 to support the probes 21, 22, 23, 24. In some embodiments, the supporting head 3 can also be configured to include the voltage measuring devices 26, 27, 28, 29 (FIG. 2), while in other embodiments these are included in detection electronics (not shown) that are in electrical communication with the probes 21, 22, 23, 24. The supporting head 3 is fixed to a displaceable stage 4, in this example, by two actuators 5 that can adjust the height of the supporting head 3 so as to bring the probes 21, 22, 23, 24 into contact with, and out of contact with, portions 20b of the substrate 20. The actuators 5 can be, for instance, hydraulic or pneumatic pistons.

The positioning device can also include a drive unit 6 adapted to move and/or displace the displaceable stage 4 in a plane. Moving the stage 4 in a plane allows the probes 21, 22, 23, 24 to be brought into registration with additional portions 20b of the substrate 20. It should be noted that the supporting head 3 can be adapted to support probe groups, where each probe group includes probes 21, 22, 23, 24 to measure a single portion 20b. For example, if supporting head 3 includes four groups of probes, four portions 20b can be tested simultaneously. As noted above, probe groups can include more than four probes, for example, six probes divided into two sets of three adjacent probes.

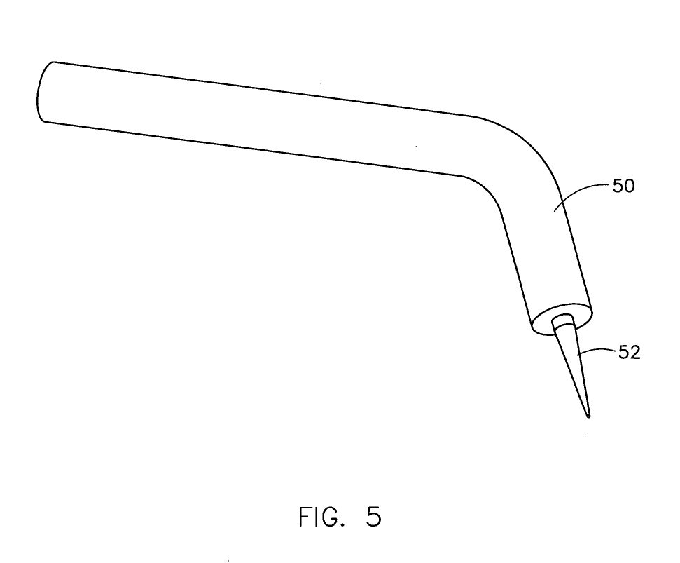

In some embodiments, as shown in FIG. 4, the drive unit 6 contains first and second electric driving motors 6a and 6b that cooperate with first and second threaded shafts 6c and 6d fixed to the displaceable stage 4. Powering the driving motors 6a or 6b causes the stage 4 to be displaced around the plane. In other embodiments translation of the stage 4 is achieved with pneumatic or hydraulic pistons.

The apparatus depicted in FIG. 3 also includes a receiving stage 7 adapted to support the substrate 20. In some embodiments the receiving stage 7 is a vacuum chuck or similar device to secure the substrate 20. In other embodiments the receiving stage 7 supports the substrate 20 only around a periphery thereof and is otherwise open from beneath. The receiving stage 7 can also be displaced in a plane by means of a drive unit 8 similar to the drive unit 6. Accordingly, some embodiments only include drive unit 8, others include only drive unit 6, and some include both.

In some embodiments a radiation source 9 is adapted to adjustably supply energy to at least one of the portions 20b to cause a non-uniform temperature disturbance therein. Radiation source 9 can be, for instance, a laser, a IR source, a microwave source, etc. Radiation source 9 can be positioned to direct radiation from either beneath the substrate 20, as shown, or from above. In further embodiments the radiation source 9 can be adapted to emit multiple beams to corresponding heat several portions 20b. This can be particularly advantageous in those embodiments in which the supporting head 3 is adapted to support several groups of probes, as described above. In some embodiments a drive unit 14 is provided to translate the radiation source 9. Translating the radiation source 9 allows radiation to be directed at selected portions 20b. The same considerations that apply to drive units 6 and 8 generally apply to drive unit 14.

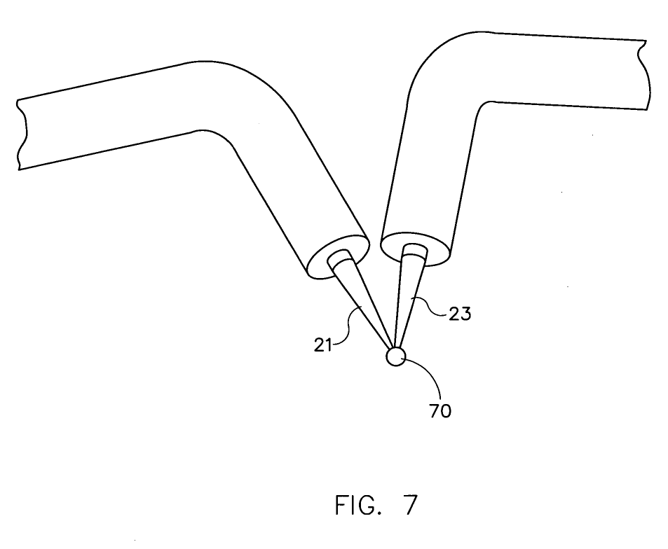

According to further embodiments, the apparatus 30 of FIG. 3 may be equipped with a non-contact thermometer (not shown) for measuring the temperature of the substrate 20 or specimen at desired locations. In still further embodiments, adjacent probes such as probes 21, 23 can be configured as thermocouples as shown in FIG. 7 such that their tips are joined together to form a single contact 70. Such a configuration is advantageous in that there is only one interface between the single contact 70 and the corresponding contact region R1 or R2, thus minimizing any potential error caused by a non-uniformity of the test specimen within the contact region R1 or R2. It will be appreciated that such a configuration is most easily implemented when the probe materials can be alloyed together.

It is to be understood that the above description is intended to be illustrative and not restrictive. Many embodiments will be apparent to those of skill in the art upon reading the above description. The scope of the invention should, therefore, be determined not with reference to the above description, but should instead be determined with reference to the appended claims, along with the full scope of equivalents to which such claims are entitled. The disclosures of all articles and references, including patent applications and publications, are incorporated herein by reference for all purposes.

1. An apparatus for determining a thermoelectric property of a sample, comprising:
a first probe set including
a first electrically conductive probe formed of a first material, and
a second electrically conductive probe formed of a second material that is different than the first material;
a second probe set including
a third electrically conductive probe formed of the first material, and
a fourth electrically conductive probe formed of the second material;
a positioning device configured to bring the first probe set into contact with a first contact region of the sample and to bring the second probe set into contact with a second contact region of the sample;
a voltage measurement system including
a first voltage sensing device configured to determine a first voltage between the first and third electrically conductive probes, and
a second voltage sensing device configured to determine a second voltage between the second and fourth electrically conductive probes; and
detection electronics configured to determine the thermoelectric property of the sample from the first and second voltages.

2. The apparatus of claim 1 wherein the voltage measurement system further includes
a third voltage sensing device configured to determine a third voltage between the first and second electrically conductive probes, and
a fourth voltage sensing device configured to determine a fourth voltage between the third and fourth electrically conductive probes; and
wherein the detection electronics is further configured to determine a first contact region temperature from the third voltage and a second contact region temperature from the fourth voltage.

3. The apparatus of claim 1 wherein the detection electronics is further configured to simultaneously determine a Seebeck coefficient of the sample and a temperature difference between the first and second contact regions from the first and second voltages.

4. The apparatus of claim 1 wherein the first and second materials each have a known Seebeck coefficient data set over a temperature range of interest.

5. The apparatus of claim 1 wherein the first and second materials include standard thermocouple materials.

6. The apparatus of claim 1 wherein the first, second, third, and fourth probes are adapted from electric contact tips for an electric contact probe station.

7. The apparatus of claim 1 wherein
the first voltage sensing device is connected to the first electrically conductive probe at a first node maintained at a reference temperature and to the third electrically conductive probe at a second node also maintained at the reference temperature, and
the second voltage sensing device is connected to the second electrically conductive probe at a third node maintained at the reference temperature and to the fourth electrically conductive probe at a fourth node also maintained at the reference temperature.

8. The apparatus of claim 7 wherein
a third voltage sensing device, configured to determine a third voltage, is connected to the first electrically conductive probe at the first node and to the second electrically conductive probe at the third node,
a fourth voltage sensing device, configured to determine a fourth voltage, is connected to the third electrically conductive probe at the second node and to the fourth electrically conductive probe at the fourth node, and
wherein the detection electronics is further configured to determine a first contact region temperature from the third voltage and a second contact region temperature from the fourth voltage.

9. The apparatus of claim 7 further comprising a thermal block in contact with the first, second, third, and fourth nodes to maintain the nodes at the reference temperature.

10. The apparatus of claim 7 further comprising a first buffer device between the first voltage sensing device and the first node and a second buffer device between the first voltage sensing device and the second node.

11. The apparatus of claim 10 further comprising a third buffer device between the second voltage sensing device and the third node and a fourth buffer device between the second voltage sensing device and the fourth node.

12. The apparatus of claim 11 further comprising a first differential amplifier configured to receive an output from each of the first and second buffer devices and a second differential amplifier configured to receive an output from each of the third and fourth buffer devices.

13. The apparatus of claim 1 further comprising a radiation source to produce a temperature gradient between the first and second contact regions.

14. The apparatus of claim 13 wherein the radiation source includes a laser.

15. The apparatus of claim 13 wherein the radiation source includes an IR source.

16. The apparatus of claim 13 wherein the radiation source includes a microwave source.

17. The apparatus of claim 1 further comprising a drive unit configured to translate the positioning device.

18. The apparatus of claim 13 further comprising a drive unit configured to translate the radiation source.

19. The apparatus of claim 1 wherein the sample is disposed on a substrate.

20. The apparatus of claim 19 further comprising a drive unit configured to translate the substrate.

21. The apparatus of claim 1 wherein at least one electrically conductive probe includes a thermal jacket.

22. The apparatus of claim 1 wherein the first and second electrically conductive probes are joined together to form a first thermocouple.

23. The apparatus of claim 22 wherein the third and fourth electrically conductive probes are joined together to form a second thermocouple.

24. The apparatus of claim 1 further comprising a non-contact IR sensor to measure a temperature of the first or second contact regions.

25. The apparatus of claim 1 wherein the detection electronics is further configured to determine the first and second voltages simultaneously.

26. A method for determining a thermoelectric property of a sample, comprising:
contacting the sample with a set of electrically conductive probes in each of two contact regions, each set of probes including a first probe of a first material and a second probe of a second material different than the first material;
measuring a first voltage between the first probes and a second voltage between the second probes; and
determining the thermoelectric property of the sample from the first and second voltages.

27. The method of claim 26 further comprising establishing a temperature gradient between the two contact regions.

28. The method of claim 26 further comprising measuring a first temperature of a first contact region of the two contact regions and measuring a second temperature of a second contact region of the two contact regions.

29. The method of claim 28 further comprising correlating the thermoelectric property to an average temperature of the first and second temperatures.

30. The method of claim 26 wherein determining the thermoelectric property of the sample includes determining a Seebeck coefficient for the first material at an average temperature, the average temperature being an average of a first temperature of the first contact region and a second temperature of the second contact region.

31. The method of claim 30 wherein the Seebeck coefficient for the first material at the average temperature is determined from a Seebeck coefficient data set for the first material.

32. The method of claim 30 wherein the Seebeck coefficient and a temperature difference between the two contact regions are determined simultaneously.

33. The method of claim 26 wherein the first and second voltages are determined simultaneously.

34. A method for determining a thermoelectric property of a sample having first and second regions, comprising:
measuring a first voltage between a first interface and a second interface, the first interface formed between a first electrically conductive material and the first region, and the second interface formed between the first electrically conductive material and the second region;
measuring a second voltage between a third interface and a fourth interface, the third interface formed between a second electrically conductive material and the first region, and the fourth interface formed between the second electrically conductive material and the second region;
measuring an average temperature of the first and second regions;
determining a Seebeck coefficient for the first and second materials at the average temperature; and
determining the thermoelectric property of the sample from the first and second voltages and the determined Seebeck coefficients for the first and second materials.

35. The method of claim 34 further comprising modulating the temperatures of the first and second regions.

36. The method of claim 34 wherein the first and second voltages are measured simultaneously.

37. A method for mapping a thermoelectric property of a sample comprising:
determining a grid for a surface of the sample, the grid specifying a number of nodes with a spacing therebetween; and
measuring a Seebeck coefficient between nodes of the grid to develop a map.

38. The method of claim 37 further including creating a temperature gradient between nodes of the grid.
